(19) United States
(12) Patent Application Publication
(10) Pub. No.: US 2016/0086930 A1
(43) Pub. Date: Mar. 24, 2016

(54) FAN-OUT WAFER LEVEL PACKAGE CONTAINING BACK-TO-BACK EMBEDDED MICROELECTRONIC COMPONENTS AND ASSEMBLY METHOD THEREFOR

(71) Applicants: Dominic Koey, Kepong Baru (MY); Zhiwei Gong, Chandler, AZ (US)

(72) Inventors: Dominic Koey, Kepong Baru (MY); Zhiwei Gong, Chandler, AZ (US)

(73) Assignee: Freescale Semiconductor, Inc., Austin, TX (US)

(21) Appl. No.: 14/494,611

(22) Filed: Sep. 24, 2014

(51) Int. Cl. H01L 25/00; H01L 25/18; H01L 23/522; H01L 21/56; H01L 21/768

(52) U.S. Cl. CPC H01L 25/50; H01L 21/565; H01L 21/76802; H01L 21/76877; H01L 21/76898; H01L 23/5226; H01L 25/18

(57) ABSTRACT

Fan-Out Wafer Level Packages (FO-WLPs) include double-sided molded package bodies in which first and second layers of components are embedded in a back-to-back relationship. In one embodiment, the FO-WLP fabrication method includes positioning a first microelectronic component carried by a first temporary substrate in a back-to-back relationship with a second microelectronic component carried by a second temporary substrate. The first and second components are overmolded while positioned in the back-to-back relationship to produce a double-sided molded package body. The first temporary substrate is then removed to expose a first principal surface of the package body at which the first component is exposed, and the second temporary substrate is likewise removed to expose a second, opposing principal surface of the package body at which the second component is exposed.

### BACKGROUND

The present invention relates generally to microelectronic packaging and, more particularly, to Fan-Out Wafer Level Packages (FO-WLPs) and methods for assembling FO-WLPs including double-sided molded package bodies in which first and second layers of components are embedded in a back-to-back relationship.

A FO-WLP includes a molded package body in which one or more microelectronic components are embedded. The embedded microelectronic components commonly include at least one semiconductor die, but can also include other devices (e.g., Surface Mount Devices or “SMDs”) and electrically-conductive structures (e.g., Embedded Ground Planes or “EGPs”). Redistribution Layers (RDLs) are built-up over the front side of the molded package body to provide the desired interconnections, and a Ball Grid Array (BGA) or other contact array is commonly produced over the frontside RDLs. In certain cases, additional RDLs are further built-up over the back side of the molded package body to produce a so-called “double-sided” FO-WLP. One or more Through Package Vias (TPVs) can be formed in the package body to provide signal communication between the frontside and backside RDLs. If desired, additional microelectronic devices can further be mounted to the backside RDLs to produce a three dimensional (3D) FO-WLP; that is, a FO-WLP including multiple levels or layers of devices, which overlap as taken along an axis extending parallel to the package centerline. Through the usage of such 3D package architectures, the device density of the FO-WLP can be increased, while the overall planform dimensions of the FO-WLP are minimized. Despite such improvements, however, still further improvements in FO-WLP device density continue to be sought. It is thus desirable to provide embodiments of a FO-WLP having an increased device density, while also having relatively compact planform dimensions. It is also desirable to provide fabrication methods suitable for fabricating such highly dense FO-WLPs on a high volume, low cost basis.

### BRIEF DESCRIPTION OF THE DRAWINGS

At least one example of the present invention will hereinafter be described in conjunction with the following figures, wherein like numerals denote like elements, and:

FIG. 1 is cross-sectional view of a FO-WLP including a double-sided molded package body in which first and second layers of components are embedded in a back-to-back relationship, as illustrated in accordance with an exemplary embodiment of the present invention;

FIGS. 2-4 are cross-sectional views illustrating a first exemplary method of forming a double-sided molded panel, which can be processed to produce a number of FO-WLPs in conjunction with the exemplary FO-WLP shown in FIG. 1;

FIGS. 5 and 6 are cross-sectional views illustrating a second exemplary method of forming a double-sided molded panel, which can be processed to produce a number of FO-WLPs in conjunction with the FO-WLP shown in FIG. 1;

FIGS. 7-12 are cross-sectional views of the FO-WLP shown in FIG. 1 assembled by processing a molded panel and shown at various stages of an exemplary manufacturing process;

FIG. 13 is cross-sectional view of a FO-WLP including a double-sided molded package body in which first and second layers of components are embedded in a back-to-back relationship, as illustrated in accordance with a further exemplary embodiment of the present invention;

FIG. 14 is an isometric view of an exemplary drop-in pillar array, which can be embedded in the molded package body of the FO-WLP shown in FIG. 13 to produce a plurality of TPVs extending between the frontside and backside RDLs; and

FIGS. 15-17 are cross-sectional views of the FO-WLP shown in FIG. 13, as illustrated at various stages of completion and produced in accordance with a further exemplary embodiment of the present invention.

For simplicity and clarity of illustration, the drawings illustrate the general manner of construction, and descriptions and details of well-known features and techniques may be omitted to avoid unnecessarily obscuring the exemplary and non-limiting embodiments of the invention described in the subsequent Detailed Description. It should further be understood that features or elements appearing in the accompanying figures are not necessarily drawn to scale unless otherwise stated. For example, the dimensions of certain elements or regions in the figures may be exaggerated relative to other elements or regions to improve understanding of embodiments of the invention.

### DETAILED DESCRIPTION

The following describes exemplary embodiments of FO-WLPs and methods for fabricating FO-WLPs containing back-to-back embedded microelectronic components. By virtue of the fabrication methods described herein, a FO-WLP can be produced including a double-sided molded package body having: (i) a first principal surface at which a first microelectronic component or a first plurality of microelectronic components is exposed, and (ii) a second, opposing principal surface at which a second microelectronic component or second plurality of microelectronic components is exposed. RDLs can be built-up over the first principal surface, the second principal surface, or both; and one or more TPVs can be formed through the molded package body to provide signal communication and power transfer between the opposing surfaces thereof. The FO-WLP can also be produced to include various other structural features, such as contact arrays, additional device planes, heat sinks, Radiofrequency (RF) antennae, RF shields, and the like; however, such structural features will vary amongst different embodiments and any description of such features should not be construed as limiting the scope of the invention. By embedding multiple levels or layers of microelectronic components in a back-to-back relationship in the molded package body, the device density of the resulting FO-WLP can be significantly increased and, in certain instances, doubled. Additional benefits of the below-described packaged architecture can also include a decreased likelihood of FO-WLP warpage and improved mechanical, electrical, and/or thermal performance.

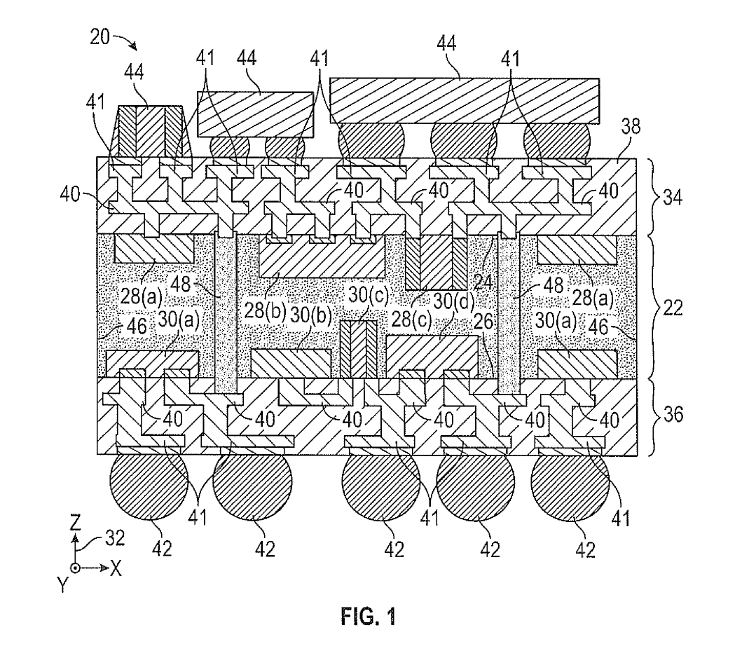

FIG. 1 is a cross-sectional view of a FO-WLP 20, as illustrated in accordance with an exemplary embodiment of the present invention. FO-WLP 20 includes a molded package body 22 having opposing principal surfaces 24 and 26. One or more microelectronic components are embedded in molded package body 22 at a position coplanar with surface 24 such that the components are exposed at or along surface 24. These components are referred to herein as the “A-side components” and are collectively identified by reference numeral “28.” Similarly, one or more microelectronic components are embedded in molded package body 22 at a position coplanar with surface 26 such that these components are exposed at surface 26. These components are referred to herein as the “B-side components” and are collectively identified by reference numeral “30.” In the illustrated example, A-side components 28 include: (i) an EGP 28(a), (ii) a semiconductor die 28(b), and (iii) an SMD 28(c). By comparison, B-side components 30 include: (i) a first semiconductor die 30(a), (ii) an EGP 30(b), (iii) an SMD 30(c), and (iv) a third semiconductor die 30(d). The instant example notwithstanding, the number and type of the number and type of microelectronic components embedded within molded package body 22 will vary amongst embodiments depending upon the design and functionality of FO-WLP 20. For example, in less complex embodiments, FO-WLP 20 can be produced to include a single A-side component and/or a single B-side component. In this case, FO-WLP 20 is still considered to contain two package layers with one or both of the package layers consisting of a single microelectronic component.

A-side components 28 are embedded in molded package body 22 in an inverted or face-up orientation such that there respective contacts are exposed at surface 24 of molded package body 22. Conversely, B-side components 30 are embedded in a non-inverted or face-down orientation such that there respective contacts are exposed at opposing surface 26 of package body 22. A-side components 28 and B-side components 30 may thus be described as positioned in an axially-opposed or back-to-back relationship. More generally, molded package body 22 can be described as having two embedded device planes along which the microelectronic components are distributed or two active sides (that is, opposing principal surfaces along which the contacts of the encapsulated components are exposed). As components 28 are distributed along a first plane (corresponding to upper principal surface 24 of molded package body 22), A-side components 28 may also be referred to as a first “embedded component layer”; while B-side components 30, which are distributed along a second plane (corresponding to lower principal surface 26 of package body 22), may be referred to as a second “embedded component layer.” In the embodiment shown in FIG. 1, A-side components 28 and B-side components 30 are non-contacting and separated by intervening regions of the mold material from which molded package body 22 is composed. An axial gap or stand-off is thus provided between A-side components 28 and B-side components 30, as taken along the Z-axis identified in FIG. 1 by coordinate legend 32.

To electrically interconnect A-side components 28 and B-side components 30, FO-WLP 20 can be produced to have a double-sided package architecture. In particular, and as indicated in FIG. 1, one or more A-side RDLs 34 can be built-up over surface 24 of molded package body 22, while one or more B-side RDLs 36 are built-up over opposing surface 26 of package body 22. A-side RDLs 34 and B-side RDLs 36 are each produced to include a dielectric body 38 containing a number of interconnect lines 40. The respective dielectric bodies 38 of RDLs 34 and 36 can be composed of a number of dielectric layers successively spun-on or otherwise deposited over the exterior of molded package body 22 in an embodiment. Interconnect lines 40 can be, for example, plated metal (e.g., copper) traces interspersed with the dielectric layers. The interconnect lines 40 contained within A-side RDLs 34 are electrically coupled to the respective contacts of A-side components 28; that is, to the bond pads of die 28(b), to the end terminals of SMD 28(c), and to the electrically-conductive surface of EGP 28(a) exposed at surface 24 of molded package body 22. Conversely, RDLs 36 are built-up over surface 26 such that the interconnect lines 40 contained therein are electrically coupled to the respective contacts of B-side components 30; that is, to the bond pads of die 30(a) and 30(d), to the end terminals of SMD 30(c), and to the electrically-conductive surface of EGP 30(b) exposed at surface 26 of package body 22. A number of solder pads 41 can further be produced in A-side RDLs 34 and/or in B-side RDLs 36 for solder bonding to one or more contact arrays or additional microelectronic devices mounted to the exterior of FO-WLP 20, as described more fully below.

Various additional structural features or devices can be mounted to or formed over RDLs 34 and 36. For example, as shown in FIG. 1, a BGA comprised of solder balls 42 can be produced over the outermost or last layer of B-side RDLs 36 (e.g., a first solder mask layer) and solder bonded to the underlying solder pads 41. Similarly, an additional device or device layer 44 can be externally mounted the outermost or last layer of A-side RDLs 34 (e.g., a second solder mask layer) and likewise solder bonded to the underlying solder pads 41. By fabricating FO-WLP 20 to include such an additional device layer 44, the overall device density of FO-WLP 20 can be further increased. This notwithstanding, the externally-mounted device layer 44 need not be included in all embodiments. For example, in alternative implementations of FO-WLP 20, device layer 44 can be replaced by a BGA or other contact array; or A-side RDLs 34 may not support any device, contact array, or other externally-mounted structure. In still further implementations, FO-WLP 20 can be produced to include another type of Input/Output (I/O) interface and associated interconnect structures, which can include any combination of contact arrays (e.g., BGAs, Land Grid Arrays, bond pads, stud bumps, etc.), RDLs, leadframes, interposers, wire bonds, through package vias, and the like. Moreover, FO-WLP 20 need not include externally-accessible points-of-contact and can instead communicate wirelessly via an antenna structure, while being powered by an internal battery or energy harvesting system.

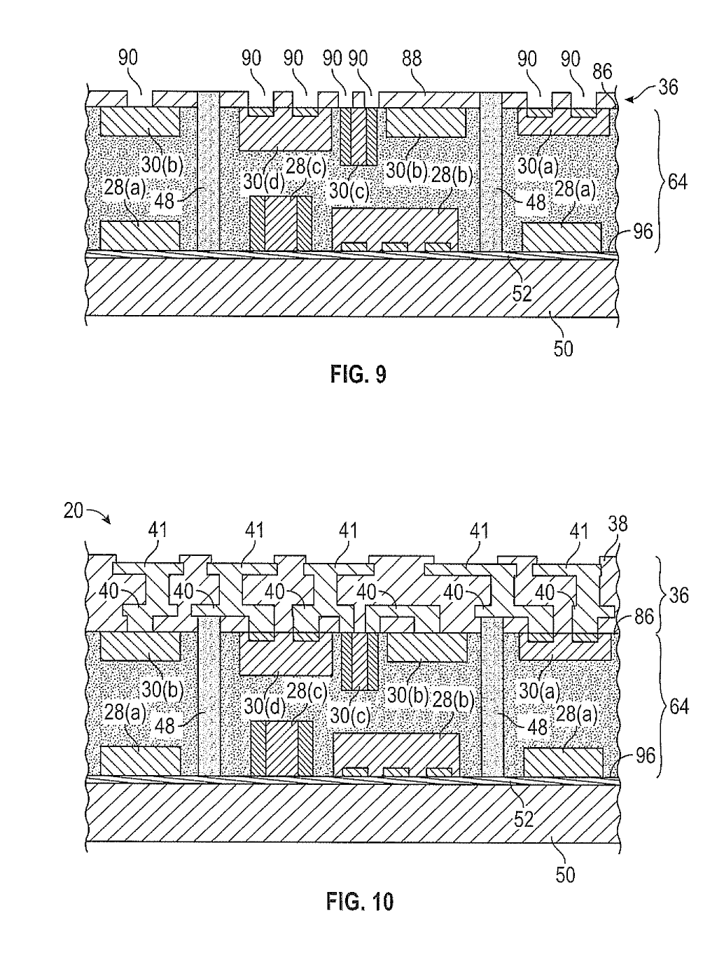

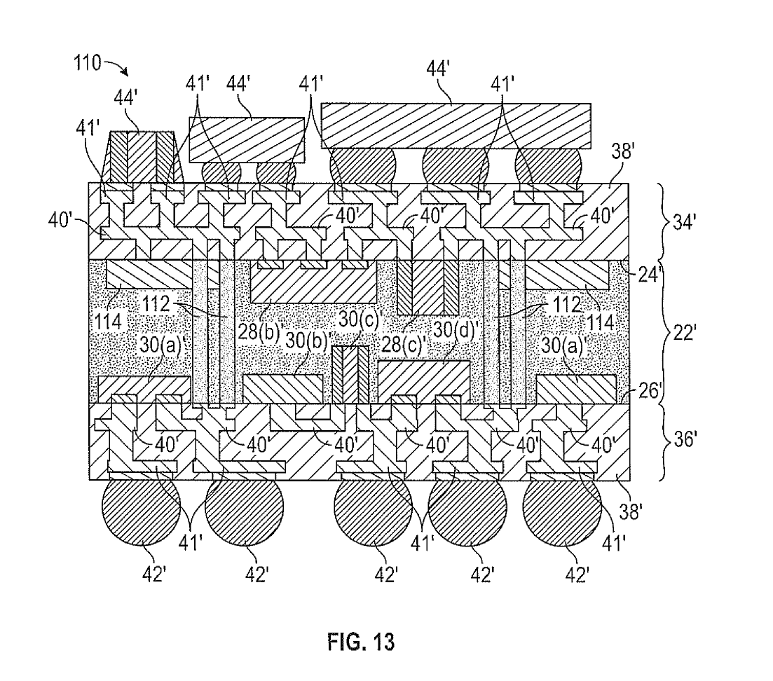

It may be desirable to provide electrical interconnection between A-side RDLs 34 and B-side RDLs 36 for signal communication and/or for power supply purposes. In this case, FO-WLP 20 can be produced to include various different types of vertical interconnect features, which electrically couple selected interconnect lines 40 contained within opposing RDLs 34 and 36. In certain embodiments, vertically-extending sidewalls traces can be printed or otherwise formed over package sidewalls 46 of molded package body 22 to interconnect RDLs 34 and 36. Additionally or alternatively, a number of TPVs 48 can be formed in molded package body 22 to provide vertical interconnection between RDLs 34 and 36. Furthermore, in other embodiments, TPVs 48 can also be utilized to provide electrical connection to the backside of the devices (e.g., die 28(b), SMD 28(c), die 30(a), SMD 30(c), or die 30(d)) or the EGPs (e.g., EGP 28(a) or EGP 30(b)) embedded within package body 22. TPVs 48 can assume the form of any electrically-conductive feature or element suitable for providing this function. As a first example, TPVs 48 can be produced as vertically-extending tunnels or via openings that have been filled with an electrically-conductive material, as described more fully below in conjunction with FIGS. 8 and 9. As a second example, TPVs 48 can be produced by embedding prefabricated metal columns or “drop-in pillars” in molded package body 22 during the overmolding or panelization process, as described more fully below in conjunction with FIGS. 13-17.

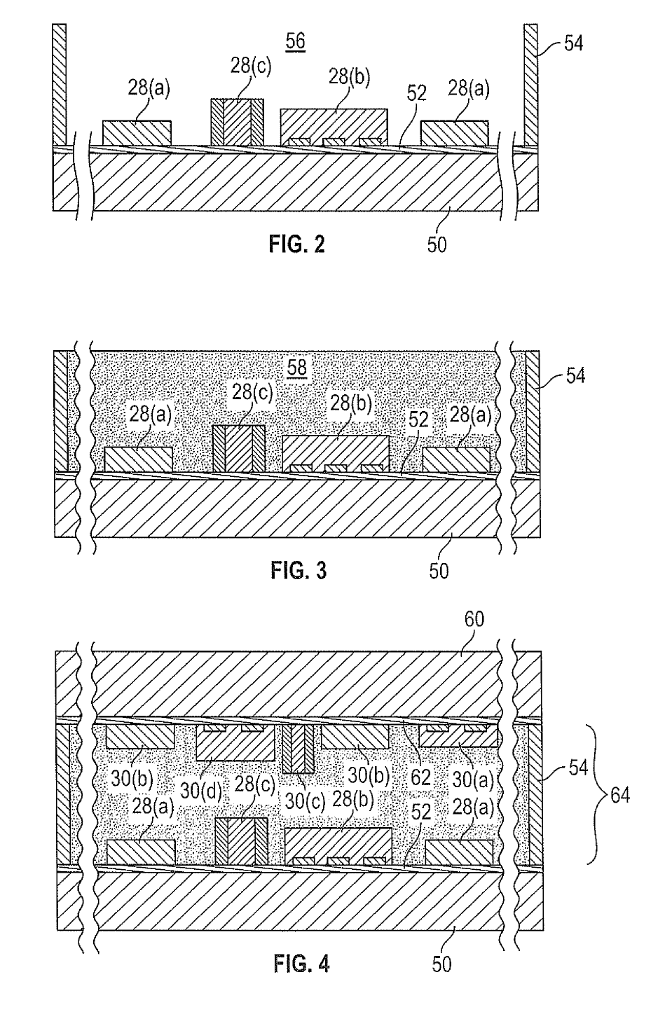

As should be appreciated from the foregoing description, FO-WLP 20 contains two layers or levels of microelectronic components 28 and 30, which are embedded within molded package body 22 in a back-to-back or axially opposed relationship. In this manner, the device density of FO-WLP 20 can be favorably increased as compared to a conventional FO-WLP having a single active side or embedded component plane. The mechanical, thermal, and/or electrical performance of FO-WLP 20 can also be enhanced due, at least in part, to a balanced component layout and decreased distances between packaged components. Additionally, FO-WLP 20 may be less prone to warpage than are other FO-WLPs having a single active side or single embedded component plane. As a still further advantage, fabrication of FO-WLP 20 can be performed substantially or entirely on a panel level to enable the production of a relatively large number of FO-WLPs in parallel. An exemplary embodiment of a manufacturing method suitable for producing FO-WLP 20 along with a number of other FO-WLPs will now be described in conjunction with FIGS. 2-12. The assembly method described below is offered by way of non-limiting example only. It is emphasized that the fabrication steps shown and described below can be performed in alternative orders, that certain steps may be omitted in alternative embodiments, and that additional steps may be performed in alternative embodiments. Furthermore, description of structure and processes known within the microelectronic package industry may be limited or entirely omitted without providing the well-known process details.

FO-WLP 20 can be fabricated in a parallel with a number of other FO-WLPs by producing and processing a double-sided mold panel. The double-sided molded panel can be produced utilizing different molding techniques including, for example, a transfer or pour molding process. An example of such a process is shown in FIGS. 2-4. Referring initially to FIG. 2, A-side components 28 can be placed on a temporary substrate 50 (e.g., a carrier or vacuum chuck) having an upper adhesive tape layer 52. As shown, A-side components 28 are positioned in a predetermined grouping or side-by-side relationship utilizing, for example, a pick-and-place tool. Although not shown in FIG. 2, it should be appreciated that the various other A-side components included within the FO-WLPs produced in parallel with FO-WLP 20 are likewise positioned in predetermined groupings across the other, non-illustrated regions of temporary substrate 50 in a manner similar to A-side components 28.

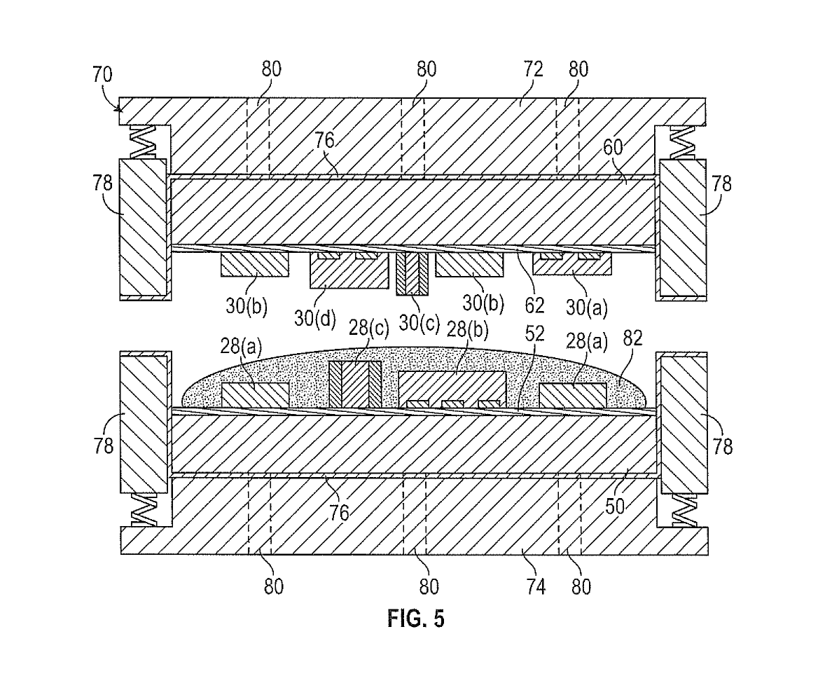

After positioning A-side components 28 on substrate 50, a mold frame 54 having a central cavity or opening 56 is further positioned over temporary substrate 50, around A-side components 28 shown in FIG. 2, and around the other non-illustrated A-side components distributed across substrate 50. A selected encapsulant or mold material 58 is then dispensed into mold frame opening 56 to form a liquid pool, as generally illustrated in FIG. 3. The dispensed mold material 58 flows over and around A-side components 28 and the other non-illustrated A-side components. While mold material 58 remains in liquid form and A-side components 28 remain at the bottom of the pool of mold material, B-side components 30 are pressed into the upper surface of the pool of mold material. In particular, as shown in FIG. 4, B-side components 30 can be positioned on a temporary substrate 60 (e.g., a carrier or vacuum chuck) having a tape layer 62, which retains components 28 in place while substrate 60 is inverted and pressed into the pool of liquid mold material 58. The liquid mold material can then be solidified by thermal curing to yield a solid molded panel 64 (identified in FIG. 4) in which A-side components 28 and B-side components 30 are embedded. In certain embodiments, only partial curing of molded panel 64 may be performed at this stage of manufacture and further curing of panel 64 may be performed at a later stage in the manufacturing process. As molded packaged body 22 (FIG. 1) is an integral part of molded panel 64, the foregoing process also results in the production of package body 22 (although the sidewalls of packaged body 22 are subsequently defined by singulation of panel 64).

There has thus been described a first exemplary process suitable for producing a double-sided molded panel, such as molded panel 64 partially shown in FIG. 4. In further embodiments, molded panel 64 can be produced utilizing other molding processes including, for example, a compression molding process. In this case, and as indicated in FIG. 5, compression molding can be carried-out utilizing a compression molding machine 70 having an upper mold portion 72, a lower mold portion 74, layers of a mold film 76 overlying the interior of mold portions 72 and 74, and spring-loaded side gates 78. A number of vacuum ports 80 (shown in phantom) can also be formed in upper mold portion 72 and lower mold portion 74. Ports 80 may be fluidly coupled to a vacuum source to remove air from the mold cavity and/or to help retain the temporary substrates 50 and 60 in place during the compression molding process. Prior to overmolding, temporary substrate 50 and A-side components 28 can be positioned in lower mold portion 74 in upright orientation. Conversely, temporary substrate 60 and B-side components 30 are position in upper mold portion 72 in an inverted orientation. Temporary substrate 60 can be held against upper mold portion 72 by engagement with physical retention features (not shown). Prior to or immediately after positioning temporary substrate 60 and B-side components 30 within compression molding machine 70, a controlled volume of mold material 82 is dispensed over temporary substrate 60 and A-side components 28. The selected mold material 82 can be, for example, a liquid or granular mold compound.

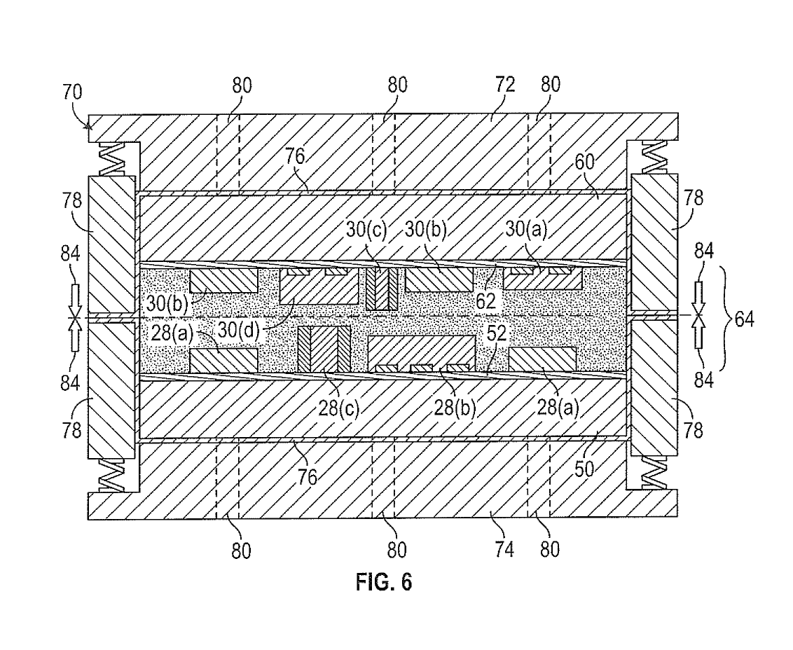

Next, as indicated in FIG. 6 by arrows 84, upper mold portion 72 and lower mold portion 74 are bought together such that aligning spring-loaded side gates 78 contact to enclose the interior of the mold. Sufficient convergent pressure and elevated temperatures are applied to the mold material 82 through substrates 50 and 60 to urge the flow of material 82 over and around A-side components 28 and B-side components 30, while material 82 cures to form a solid or semisolid body. Double-sided molded panel 64 is thus formed between temporary substrates 50 and 60, as shown in FIG. 6. During the compression molding process, air can also be removed from the mold material through vacuum ports 80 to minimize or eliminate voiding within molded panel 64. After formation of double-sided molded panel 64, molding machine 70 is opened and mold film 76 advanced to remove molded panel 64, temporary substrate 50, and temporary substrate 60 from molding machine 70 for further processing, as described more fully below. As molded packaged body 22 (FIG. 1) is an integral part of molded panel 64, the foregoing process also results in the production of package body 22.

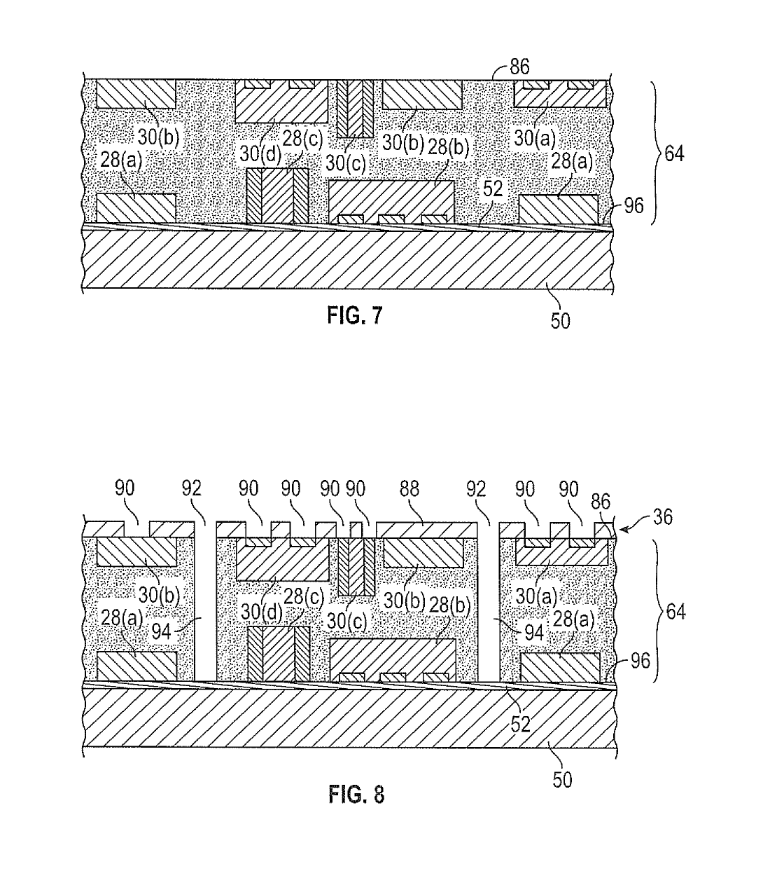

After production of double-sided molded panel 64, a build-up process can be performed to produce RDLs over the opposing principal surfaces of molded panel 64. If desired, TPVs 48 (FIG. 1) can be produced immediately prior to or in conjunction with the early stages of double-sided RDL build-up. In one approach, and referring now to FIG. 7, temporary substrate 50 is first removed from molded panel 64 to reveal principal surface 86 of molded panel 64 (therefore, also revealing surface 26 of molded package body 22 shown in FIG. 1). Temporary substrate 50 can be removed utilizing, for example, a thermal release process. After removal of temporary substrate 50, first photoimagable dielectric layer 88 included within B-side RDLs 36 is deposited over surface 86 by, for example, spin-on application. Dielectric layer 88 is then lithographically patterned to form a number of openings 90 through which the contacts of B-side components 30 are exposed (shown in FIG. 8). Openings 92 are also formed dielectric layer 88 over the locations of molded panel 64 at which TPVs 48 (FIG. 1) are desirably formed. Laser drilling, mechanical drilling, or other suitable material removal technique is then performed to produce a plurality of via openings 94 (FIG. 8) in molded panel 64 and extending from principal surface 86 to the opposing principal surface 96 thereof. Via openings 94 are subsequently filled with an electrically-conductive material, such as a solder paste or a metal-filled epoxy, to produce TPVs 48. The resultant structure is shown in FIG. 9.

Advancing to FIG. 10, the remainder of B-side RDLs 36 are now produced over surface 86 of double-sided molded panel 64 (and, therefore, surface 24 of molded package body 22 shown in FIG. 1). During build-up of B-side RDLs 36, dielectric body 38 can be deposited by spinning-on or otherwise applying one or more dielectric layers over surface 86 of molded panel 64. As noted above, interconnect lines 40 are interspersed with the deposited dielectric layers and can be produced using well-known lithographical patterning and conductive material deposition techniques. In one embodiment, interconnect lines 40 are produced by patterning a mask layer deposited over a seed layer, plating exposed regions of the seed layer with copper or another metal, and then removing the mask layer to define interconnect lines 40. Finally, solder pads 41 can also be produced in contact with interconnect lines 40, and solder mask openings can be formed in the outermost RDL 36 (e.g., a solder mask layer) by photolithographical patterning.

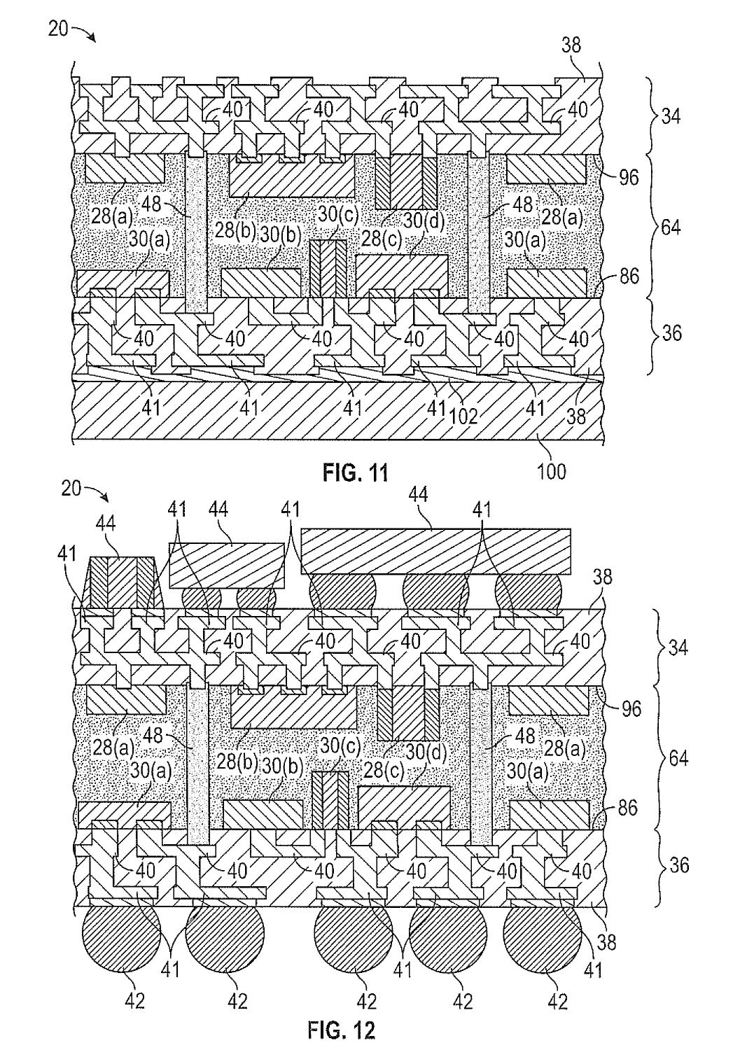

Continuing with the exemplary FO-WLP fabrication method, double-sided molded panel 64 is next inverted and attached to a new carrier for B-side RDL build-up. For example, and with reference to FIG. 11, molded panel 64 can be attached to a substrate 100 (e.g., a carrier or chuck). In the illustrated embodiment, substrate 100 includes an upper taper layer 102 to which the newly-produced B-side RDLs 36 are adhered. As further indicated in FIG. 11, substrate 50 (FIG. 10) is thermally released or other removed to reveal principal surface 96 of molded panel 64 (and, therefore, surface 26 of molded package body 22 shown in FIG. 1). As the respective contacts of the A-side components 28 are exposed at surface 96 of panel 64, an RDL build-up process similar to that described above can now be carried-out. The RDL build-up process results in the production of A-side RDLs 34 including solder pads 41 over surface 96 of molded panel 64. Afterwards, BGA solder balls 42 are produced in contact with solder pads 41 of B-side RDLs 36 utilizing, for example, a ball attach and solder reflow process. Prior to or following production of BGA 42, externally-mounted microelectronic devices 44 can be bonded to solder pads 41 of A-side RDLs 34 to yield the structure shown in FIG. 12. Finally, molded panel 64 can be singulated to produce a plurality of discrete FO-WLPs including completed FO-WLP 20, as shown in FIG. 1. Singulation is preferably carried-out using a dicing saw; however, other singulation processes can also be used including, for example, laser cutting and water jetting. As may be appreciated by comparing FIG. 12 to FIG. 1, singulation liberates molded package body 22 from molded panel 64 and imparts package body 22 with substantially vertical sidewalls. Molded package body 22 is thus produced as a singulated piece of molded panel 64, as are the molded packaged bodies of the other FO-WLPs produced in parallel with FO-WLP 20.

There has thus been described exemplary methods for assembling an FO-WLP including a double-sided molded package body in which first and second layers of components are embedded in a back-to-back relationship. As described above, embodiments of the FO-WLP assembly process can be largely or wholly carried-out on a panel level to produce a relatively large number of FO-WLPs in parallel to maximize throughput and manufacturing efficiency, while reducing overall production costs. In the above-described exemplary embodiment, FO-WLPs were assembled (e.g., FO-WLP 20 shown in FIG. 1) that included TPVs formed using a via-last “drill and fill” process. It will be appreciated that, in such embodiments, the via openings can be produced prior to RDL build-up or at any juncture during RDL build-up such that the filled vias can extend to or partially through the A-side or B-side RDLs. However, various other processes can also be used to produce any TPVs included within the FO-WLPs. For example, in further embodiments, the FO-WLPs can be fabricated to include TPVs formed by embedding prefabricated, electrically-conductive members, such as metal pillars, at selected locations in the molded package bodies during the overmolding or panelization process. To further illustrate this point, an exemplary embodiment of an FO-WLP containing such prefabricated TPVs is described in conjunction with FIG. 13. Still further examples of TPV formation processes suitable for integration into embodiments of the FO-WLP fabrication method can be found in U.S. Pub. 2013/0049217 A1, filed Aug. 12, 2011, and entitled “SEMICONDUCTOR DEVICE PACKAGING HAVING PRE-ENCAPSULATION THROUGH VIA FORMATION USING DRPO-IN SIGNAL CONDUITS,” as well as in U.S. Pub. 2013/0049192 A1, filed Feb. 22, 2012, and entitled “STACKED CHIP PACKAGE AND FABRICATION METHOD THEREOF.”

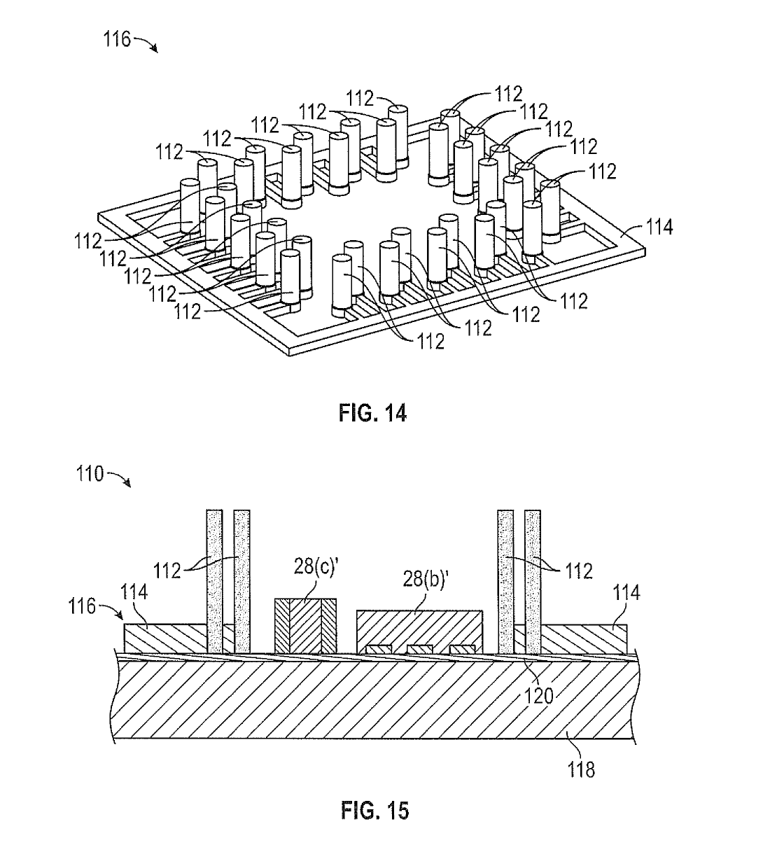

FIG. 13 is a cross-sectional view of a FO-WLP 110, as illustrated in accordance with a further exemplary embodiment of the present invention. In many respects, FO-WP 110 is similar to FO-WLP 20 shown in FIG. 1. Accordingly, like reference numerals have been utilized to denote like structural elements, but with the addition of a prime (′) symbol to indicate that FO-WLP 110 (FIG. 13) and FO-WLP 20 (FIG. 1), and their respective features, can differ to varying extents. As can be seen in FIG. 13, FO-WLP 110 includes a number of TPVs 112, which have been embedded in molded package body 22′ and which extend between opposing principal surfaces 24′ and 26′. In this case, TPVs 112 are produced as electrically-conductive (e.g., copper) columns or pillars, which have been preplaced in their desired positions prior to overmolding or panelization. Stated differently, TPVs 112 are discrete structures that have been positioned laterally adjacent selected components 28′ 30′ formation of molded package body 22′ and, more generally, the molded panel from which packaged body 22′ is produced. A TPV frame 114 is further embedded in molded package body 22′ and cooperates with TPVs 112 to form a prefabricated TPV array 116. TPV array 116 is further illustrated in FIG. 14 and can be utilized to maintain TPVs 112 in their desired position during the below-described overmolding or panelization process. In embodiments wherein it is desired to provide electrical isolation between TPVs 112, TPV frame 114 can be composed of a body of dielectric material through which TPVs 112 extend. In alternative embodiments, TPV frame 114 can be composed of an electrically-conducive material and, thus, serve as an EGP to which TPVs 112 provide an electrical connection. In this latter case, TPVs 112 and TPV frame 114 are conveniently produced as single metal (e.g., copper) piece.

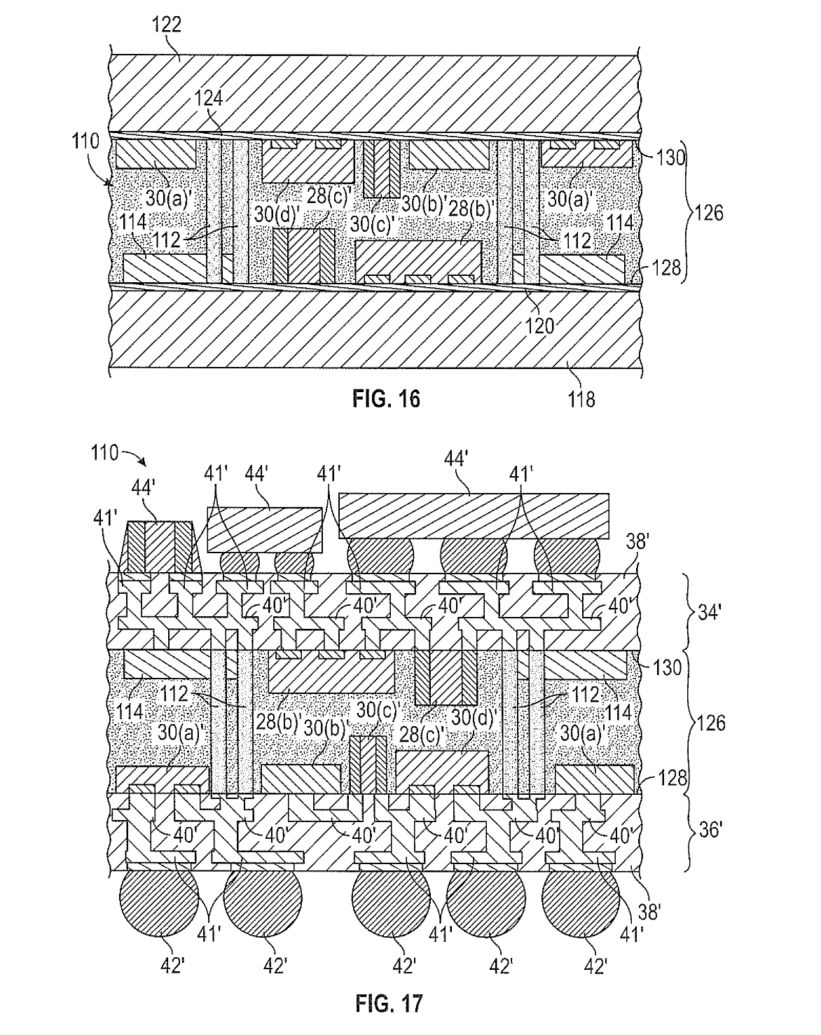

During fabrication of FO-WLP 110, TPV array 116 and the other A-side components 28′ are positioned on a temporary substrate 118 having an upper tape layer 120, as shown in FIG. 15. Similarly, B-side components 30′ are positioned on a temporary substrate 122 having a tape layer 124, as shown in FIG. 16. Temporary substrate 122 can then be inverted, positioned over temporary substrate 118, and B-side components 30′ embedded in a double-sided molded panel 126 in a back-to-back relationship with A-side components 28′. The region of double-sided molded panel 126 corresponding to FO-WLP 110 is shown in FIG. 16. A pour and press molding process of the type described above in conjunction with FIGS. 2-4, a compression molding process of the type described above in conjunction with FIGS. 5 and 6, or a different encapsulation process can be utilized to produce molded panel 126 between substrates 118 and 122, as desired. Afterwards, RDLs 34′ and 36′ can be built-up over principal surfaces 128 and 130, respectively, of panel 126; outer component layer containing microelectronic devices 44′ can be mounted to A-side RDLs 34′; and BGA solder balls 42′ can be produced over B-side RDLs 36′. The resultant structure is shown in FIG. 17 prior to singulation of molded panel 126. Finally, double-sided molded panel 126 can be singulated to produce FO-WLP 110 shown in FIG. 13 along with a number of other FO-WLPs.

There has thus been provided exemplary embodiments of FO-WLPs and methods for fabricating FO-WLPs containing back-to-back embedded microelectronic components. By virtue of the fabrication methods described above, FO-WLPs are produced to include first and second layers of components embedded in a back-to-back relationship with each component layer containing one or more microelectronic components, such as semiconductor die, SMDs, EGPs, or the like. By embedding multiple layers of microelectronic components in a back-to-back relationship in the molded package body, the device density of the resulting FO-WLP can be favorably increased. Stated differently, the above-described fabrication methods enable the production of a highly dense FO-WLP through the creation of an additional plane of microelectronic components embedded inside the encapsulant or molded body. In certain cases, such a packaged architecture may also favorably enhance the functionally of the resulting 3D FO-WLP, such as a System-in-Package (SIP) FO-WLP. In certain embodiments, improved mechanical, thermal, and/or electrical performance can also be achieved due, at least in part, to a more balanced component layout and reduced distances between the embedded components and/or any contact or contact arrays produced over the exterior of FO-WLP. The likelihood of FO-WLP warpage can also be reduced by virtue of the above-described package architectures. Finally, as described above, embodiments of the FO-WLP can be produced using a panel level fabrication process to maximize manufacturing efficiency, while minimizing overall production costs

In one embodiment, the above-described assembly method includes the step or process of positioning a first microelectronics component or group of microelectronics components carried by a first temporary substrate in a back-to-back relationship with a second microelectronic component or group of microelectronic components carried by a second temporary substrate. The first and second microelectronic components are overmolded while positioned in the back-to-back relationship to produce a double-sided molded package body, which may or may not be contained within a larger molded panel at this juncture of fabrication. The first temporary substrate is then removed to expose a first principal surface of the double-sided molded package body at which the first microelectronic component is exposed, and the second temporary substrates is likewise removed to expose a second, opposing principal surface of the double-sided molded package body at which the second microelectronic component is exposed.

In another embodiment, the above-described FO-WLP assembly method includes the step or process of positioning a first plurality or grouping of microelectronics components carried by a first temporary substrate in a back-to-back relationship with a second plurality or grouping of microelectronic components carried by a second temporary substrate. After positioning the first and second pluralities of microelectronic components in the back-to-back relationship, a double-sided molded panel is formed between the first and second temporary substrates. After positioning the first and second pluralities of microelectronic components in the back-to-back relationship, a double-sided molded panel is formed between the first and second temporary substrates. The double-sided molded panel has a first panel surface at which the first plurality of microelectronic components is exposed and a second, opposing panel surface at which the second plurality of microelectronics components is exposed. The double-sided molded panel is then singulated to yield a plurality of FO-WLPs. Each FO-WLP includes at least a first microelectronic component from the first plurality of microelectronic components, at least a second microelectronic component from the second plurality of microelectronic components, and a molded package body in which the first and second microelectronic components are embedded.

Embodiments of FO-WLPs have further been provided. In one embodiment, the FO-WLP includes a molded package body having a first surface and a second surface opposite the first surface. A first microelectronic component is embedded in the molded package body at a position substantially coplanar with the first surface. A second microelectronic component is likewise embedded in the molded package body at a position coplanar with the second surface such that the first and second microelectronic components are positioned in a non-contacting, back-to-back relationship. In certain embodiments, the molded package body can assume the form of a monolithic or unitary body singulated from a larger molded panel. At least a first RDL can be formed over the first surface and may contain interconnect lines electrically coupled to the first microelectronic component, and at least a second RDL formed over the second surface and containing interconnect lines electrically coupled to the second microelectronic component. If desired, the FO-WLP can further include at least one TPV extending from the first surface to the second surface of the molded package body and electrically coupling one of the interconnect lines contained within the first RDL to one of the interconnect lines contained within the second RDL.

While at least one exemplary embodiment has been presented in the foregoing Detailed Description, it should be appreciated that a vast number of variations exist. It should also be appreciated that the exemplary embodiment or exemplary embodiments are only examples, and are not intended to limit the scope, applicability, or configuration of the invention in any way. Rather, the foregoing Detailed Description will provide those skilled in the art with a convenient road map for implementing an exemplary embodiment of the invention. It being understood that various changes can be made in the function and arrangement of elements described in an exemplary embodiment without departing from the scope of the invention as set-forth in the appended claims.

As appearing in the foregoing Detailed Description, terms such as “comprise,” “include,” “have,” and the like are intended to cover non-exclusive inclusions, such that a process, method, article, or apparatus that comprises a list of elements is not necessarily limited to those elements, but can include other elements not expressly listed or inherent to such process, method, article, or apparatus. As still further appearing herein, terms such as “over,” “under,” “on,” and the like are utilized to indicate relative position between two structural elements or layers and not necessarily to denote physical contact between structural elements or layers. Thus, a first structure or layer can be described as fabricated “over” or “on” a second structure, layer, or substrate without indicating that the first structure or layer necessarily contacts the second structure, layer, or substrate due to, for example, presence of one or more intervening layers. As appearing further herein, the term “microelectronic component” is utilized in a broad sense to refer to an electronic device, element, or structure produced on a relatively small scale and amenable to packaging in the above-described manner. Microelectronic components include, but are not limited to, integrated circuits formed on semiconductor die, Microelectromechanical Systems (MEMS) devices, passive electronic microelectronic components, optical devices, and other small scale electronic devices capable of providing processing, memory, sensing, radiofrequency, optical, and actuator functionalities, to list but a few examples. Microelectronic components also include other discrete or separately-fabricated structures that can be integrated into the package, such as preformed via structures and preformed antenna structures.

1. A method for assembling a Fan-Out Wafer Level Package (FO-WLP), comprising:
dispensing a mold material over a first temporary substrate;
positioning a first microelectronic component carried by a the first temporary substrate in back-to-back relationship with a second microelectronic component carried by a second temporary substrate;
overmolding the first and second microelectronic components while positioned in the back-to-back relationship to produce a double-sided molded package body;
removing the first temporary substrate to expose a first principal surface of the double-sided molded package body at which the first microelectronic component is exposed;
removing the second temporary substrate to expose a second, opposing principal surface of the double-sided molded package body at which the second microelectronic component is exposed;
forming one or more Redistribution Layers (RDLs) over the first principal surface of the molded package body after removal of the first temporary substrate and prior to removal of the second temporary substrate; and
bonding at least one externally-mounted microelectronic device to the one or more RDLs over the first principal surface.

2. The method of claim 1, wherein the positioning comprises:
adhering the first microelectronic component to a tape layer of the first temporary substrate; and
positioning the first temporary substrate adjacent the secondary temporary substrate, while the second temporary substrate and the second microelectronic component carried thereby is inverted.

3. The method of claim 1, wherein positioning comprises positioning the first and second microelectronic components in the back-to-back relationship such that an axial stand-off is provided between the first and second microelectronic components.

4. The method of claim 1, further comprising:
positioning one or more electrically-conductive pillars laterally adjacent the first and second microelectronic components; and
overmolding the electrically-conducive pillars along with the first and second microelectronic components to produce electrically-conductive vias extending between the opposing principal surfaces of the double-sided molded package body.

5. The method of claim 1, further comprising;
forming via openings through the double-sided molded package body; and
filling the via openings with an electrically-conductive material to produce Through Package Vias extending between the opposing principal surfaces of the double-sided molded package body.

6. The method of claim 1, further comprising:
forming one or more RDLs over the second, opposing principal surface of the molded package body after removal of the second temporary substrate and production of the RDLs over the first principal surface.

7. The method of claim 1, wherein overmolding comprises:
exerting a convergent force on the first and second temporary substrates to urge flow of the mold material over and around the first and second microelectronic components; and
at least partially curing the mold material to produce the double-sided molded package body.

8. The method of claim 1, wherein dispensing comprises dispensing the mold material, in liquid or granular form, over the first temporary substrate.

9. The method of claim 1, wherein forming comprising:
placing a mold frame on the first temporary substrate, the mold frame having an opening in which the first microelectronic component is received;
dispensing a liquid mold material into the opening to form a pool of mold material in which the first microelectronic component is submerged;
inverting the second temporary substrate and pressing the second microelectronic component into the pool of mold material; and
at least partially curing the mold material to produce the double-sided molded package body.

10. The method of claim 1, wherein overmolding comprises overmolding the first and second microelectronic components along with a number of other microelectronic components to produce a molded panel of which the molded package body is a part.

11. A method for assembling Fan-Out Wafer Level Packages (FO-WLPs), comprising:
dispensing a mold material over a first temporary substrate;
positioning a first plurality of microelectronic components carried by the first temporary substrate in a back-to-back relationship with a second plurality of microelectronic components carried by a second temporary substrate;
after positioning the first and second pluralities of microelectronic components in the back-to-back relationship, forming a double-sided molded panel between the first and second temporary substrates having a first panel surface at which the first plurality of microelectronic components is exposed and having a second, opposing panel surface at which the second plurality of microelectronic components is exposed;
forming one or more Redistribution Layers (RDLs) over the first principal surface after removing of the first temporary substrate from the molded panel;
bonding a plurality of externally-mounted microelectronic devices to the one or more RDLs over the first principal surface; and
singulating the double-sided molded panel to yield a plurality of FO-WLPs, each FO-WLP including at least a first microelectronic component from the first plurality of microelectronic components, at least a second microelectronic component from the second plurality of microelectronic components, a molded package body in which the first and second microelectronic components are embedded, and at least one of the plurality of externally-mounted microelectronic devices on the one or more RDLs over the first principal surface.

12. The method of claim 11, wherein positioning comprises:
adhering the first plurality of microelectronic components to a tape layer of the first temporary substrate; and
placing the first temporary substrate adjacent the second temporary substrate, while the first temporary substrate is inverted to position the first and second pluralities of microelectronic components in the back-to-back relationship.

13. The method of claim 11, wherein positioning comprises placing the first and second pluralities of microelectronic components in the back-to-back relationship, while preventing contact therebetween.

14. The method of claim 11, wherein forming the double-sided molded panel comprises:
urging the first and second temporary substrates together under elevated temperature conditions to produce the double-sided molded panel in which the first and second pluralities of microelectronic devices are embedded.

15. The method of claim 11, wherein forming the double-sided molded panel comprises:
dispensing a pool of mold material over the first plurality of microelectronic devices;
pressing the second plurality of microelectronic devices into an upper surface of the pool of mold material; and
at least partially curing the pool of mold material to produce the double-sided molded panel in which the first and second pluralities of microelectronic devices are embedded.

16. The method of claim 11, further comprising:
producing one or more additional RDLs over the second, opposing principal surface after removing the second temporary substrate from the molded panel, the RDLs and additional RDLs produced prior to singulation of the molded panel.

17-20. (canceled)
